(19) United States
(12) Patent Application Publication
(10) Pub. No.: US 2024/0063025 A1
(43) Pub. Date: Feb. 22, 2024

(54) SACRIFICIAL PASSIVATION FILM DEPOSITION METHOD, TRENCH ETCHING METHOD AND SEMICONDUCTOR PROCESSING APPARATUS USING LOW-TEMPERATURE ALD PROCESS

(71) Applicant: SEMES CO., LTD., Chungcheongnam-do (KR)

(72) Inventors: Jin Hee HONG, Chungcheongnam-do (KR); Yun Sang KIM, Chungcheongnam-do (KR); Min Sung JEON, Chungcheongnam-do (KR); Young Eun JEON, Chungcheongnam-do (KR); Sung Min CHOI, Chungcheongnam-do (KR); Young Jo JIN, Chungcheongnam-do (KR); Dong Young JANG, Chungcheongnam-do (KR)

(21) Appl. No.: 18/213,894

(22) Filed: Jun. 26, 2023

(30) Foreign Application Priority Data
Aug. 11, 2022 (KR) 10-2022-0100625

(51) Int. Cl. H01L 21/311; H01L 21/67

(52) U.S. Cl. CPC H01L 21/31116; H01L 21/67069

(57) ABSTRACT

A sacrificial passivation film deposition method according to an exemplary embodiment of the present disclosure may include: depositing a primary sacrificial passivation film on an entire surface of a substrate using a thermal ALD (T-ALD) process; and additionally depositing a secondary sacrificial passivation film on an upper surface and at least a portion of a side surface of an upper portion of the primary sacrificial passivation film using a plasma-ALD (P-ALD) process.

### CROSS-REFERENCE TO RELATED APPLICATION(S)

This application claims benefit of priority to Korean Patent Application No. 10-2022-0100625 filed on Aug. 11, 2022 in the Korean Intellectual Property Office, the present disclosure of which is incorporated herein by reference in its entirety.

### BACKGROUND

### 1. Field

The present disclosure relates to a sacrificial passivation film deposition method, a trench etching method, and a semiconductor processing apparatus using a low-temperature atomic layer deposition (ALD) process, and more particularly, to a sacrificial passivation film deposition method, a trench etching method, and a semiconductor processing apparatus for forming a sacrificial passivation film using a thermal ALD process and a plasma ALD process at a low-temperature.

### 2. Description of Related Art

When trench etching is performed using plasma, a side surface of an upper portion, a surface of the trench to be etched is over-etched due to repeated contact with the plasma compared to a side surface of a lower portion, causing a bowing or tapering phenomenon.

For example, as illustrated FIG. 1, as the thicknesses of a channel hole mask (CHM) and a channel hole (CHH) increased in the manufacture of a 3D-NAND flash memory in which memory cells are stacked in multiple layers, an amorphous carbon layer (ACL) and an oxide-nitride-oxide-nitride layer (ONON layer), which are films to be etched on each side surface of an upper portion, form a bow with a high contact rate with plasma, and as a result, electrical characteristics of a semiconductor device were inhibited. In order to improve the performance of the semiconductor device, it is necessary to manufacture the upper and lower portions of the trench to have the same width (critical dimension, CD) without structural deformation.

Therefore, conventionally, excessive loss of the film to be etched has been prevented by depositing a silicon-based sacrificial passivation film on the film to be etched in order to prevent bowing and tapering phenomena that cause the upper and lower widths to be different. Since the sacrificial passivation film should be easily removed after achieving the purpose, an ALD process capable of depositing a fine thin film has been introduced into the manufacture of the sacrificial passivation film. The ALD process, unlike a chemical vapor deposition (CVD) method, manufactures a micro-thin film with a deposition mechanism based on a self-limiting surface chemical reaction by independently injecting a reactant.

Conventional Patent Document 1, in the case of a ALD process of SiO₂, a Si precursor such as bistertiary-butylamino silane (BTBAS) is injected as a reactant in a first step to form a portion of a deposited film through a physical/chemical adsorption reaction with an interface, O₂ is injected as a reactant in a second step, and a SiO₂ monolayer of several A level is deposited on a wafer surface by plasma generation, and this process is repeated a plurality of times to complete a straight thin film of a desired thickness. As such, the ALD (plasma-ALD, P-ALD) process of SiO₂ using plasma has been used to manufacture a sacrificial passivation film for the CHM. In the P-ALD method, a thickness of the deposited film varies according to the contact rate with plasma, and as illustrated in FIG. 2, the film to be etched may be protected by manufacturing a SiO₂ sacrificial passivation film on an upper surface and a side surface of an upper portion of a structural substrate in a process of several cycles.

However, as the semiconductor device manufacturing market is increasingly demanding a trench etching technology of a high aspect ratio, P-ALD technology alone has limitation in protecting a film to be etched. For example, the 3D-NAND flash memory market is promoting the development of ultra-high-layer memory cell technology to increase storage capacity while limiting the number of CHHs for low data loss and high data rate. For this reason, since the etching depth of the CHM and CHH gradually increases, the surface to be etched of a side surface of a lower portion where the sacrificial passivation film is not formed as shown in the last step of FIG. 2 is lost as etching proceeds, making it difficult to implement vertical etching with a constant width for each trench depth.

In addition, in order to solve this problem, Patent Document 2 used a thermal atomic layer deposition (T-ALD) process, which is another sacrificial passivation film deposition method, wherein the T-ALD process is an isotropic atomic layer deposition (i-ALD) technology capable of depositing an entire surface without affecting a surface structure of the substrate by diffusing/moving reactive species in all directions, and is a method of activating a surface chemical reaction by using thermal energy for deposition. In the case of depositing a sacrificial passivation film by the T-ALD process, it is usually necessary to perform the deposition using thermal energy at a temperature of 200 to 400° C.

However, unlike the T-ALD process, since the trench etching process is performed in a lower temperature range than the conditions presented above, there is a hardware technical limitation in rapidly changing the temperature in one chamber. Therefore, productivity was secured by manufacturing a substrate pattern to have a vertical profile by transferring the substrate between two independent devices (a low-temperature etching device and a high-temperature deposition device), but a rapid increase in cost occurred in terms of facilities.

In addition, in the T-ALD process, since a high-purity film in which crystals are formed very densely is deposited due to high-temperature thermal energy. Thus, after the trench etching process is completed, a separate heat treatment process (at least 500° C.) is additionally required to remove the sacrificial passivation film, and additional costs and time for a sacrificial passivation film removal process result in reduced productivity.

Therefore, in order to reduce consumed time and costs, the necessity to develop a low-temperature deposition process technology capable of producing a sacrificial passivation film in one etching device has increased, and furthermore, after the role of the sacrificial passivation film was completed, the manufacturing of a sacrificial passivation film having a film-like structure capable of being easily removed in an etching step, which is the next process, has been demanded.

### SUMMARY

An aspect of the present disclosure may provide a sacrificial passivation film deposition method, a trench etching method, and a semiconductor processing apparatus using a low-temperature atomic layer deposition (ALD) process capable of depositing a sacrificial passivation film at a low-temperature during a trench etching process.

According to an aspect of the present disclosure, a sacrificial passivation film deposition method using a low-temperature atomic layer deposition (ALD) process may include: depositing a primary sacrificial passivation film on an entire surface of a substrate using a thermal ALD (T-ALD) process; and additionally depositing a secondary sacrificial passivation film on an upper surface and a side surface of an upper portion of the primary sacrificial passivation film using a plasma-ALD (P-ALD) process.

According to another aspect of the present disclosure, a trench etching method using a low-temperature atomic layer deposition (ALD) process may include: depositing a target layer on a substrate; etching a portion of the target layer; and completing etching of the target layer, wherein the etching of the portion of the target layer may include: depositing a primary sacrificial passivation film on an entire surface of the target layer using a thermal ALD (T-ALD) process; and additionally depositing a secondary sacrificial passivation film on an upper surface and a side surface of an upper portion of the primary sacrificial passivation film using a plasma-ALD (P-ALD) process.

According to an aspect of the present disclosure, a semiconductor processing apparatus performing a sacrificial passivation film deposition method using the low-temperature ALD process as described above or a trench etching method using the low-temperature ALD process as described above may include: a first chamber depositing the primary sacrificial passivation film on the target layer, and a second chamber depositing the secondary sacrificial passivation film on the primary sacrificial passivation film.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view illustrating a bowing phenomenon occurring when trench etching is performed in the prior art;

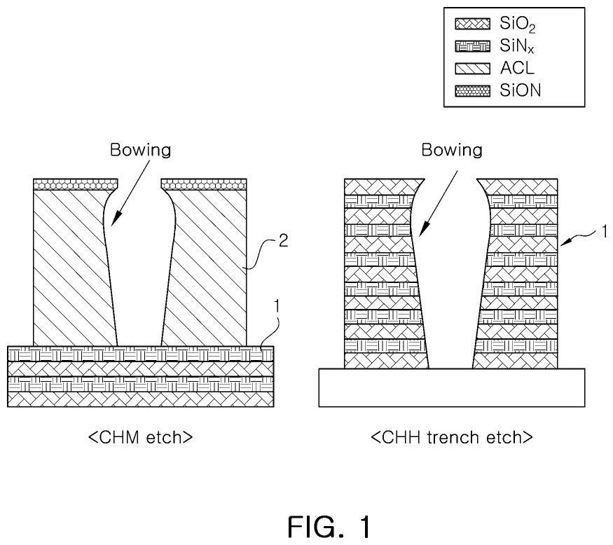

FIG. 2 is a view illustrating a sacrificial passivation film deposition process and an etching process in the prior art;

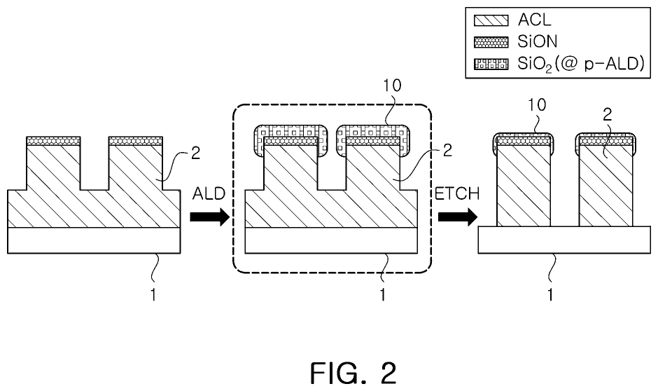

FIG. 3 is a view illustrating a process of a sacrificial passivation film deposition method using a low-temperature ALD process according to an exemplary embodiment of the present disclosure;

FIG. 4 is a flow chart of a sacrificial passivation film deposition method using a low-temperature ALD process according to an exemplary embodiment of the present disclosure;

FIG. 5 is a view illustrating one cycle of a sacrificial passivation film deposition method using a low-temperature ALD process according to an exemplary embodiment of the present disclosure;

FIG. 6 is a view illustrating application of a trench etching method using a low-temperature ALD process according to an exemplary embodiment of the present disclosure to a CHM manufacturing process;

FIG. 7 is a view illustrating application of a trench etching method using a low-temperature ALD process according to an exemplary embodiment of the present disclosure to a CHH manufacturing process;

FIG. 8 is graphs illustrating experimental results obtained by performing a T-ALD process according to an exemplary embodiment of the present disclosure using BTBAS and a silylamine compound; and

FIG. 9 is graphs comparing experimental results obtained by performing a P-ALD process according to an exemplary embodiment of the present disclosure using BTBAS and a silylamine compound.

### DETAILED DESCRIPTION

Hereinafter, exemplary embodiments of the present disclosure will now be described in detail with reference to the accompanying drawings.

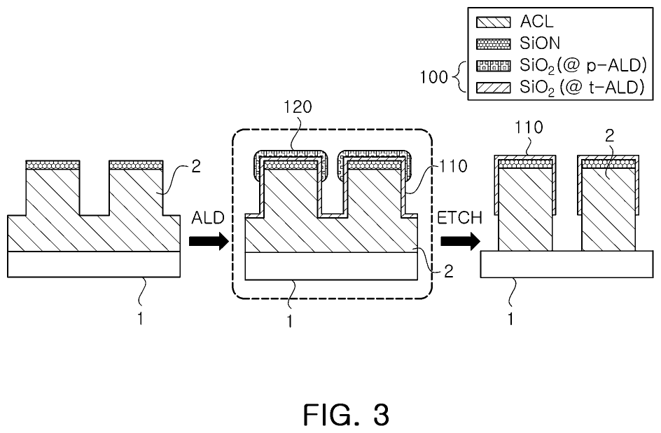

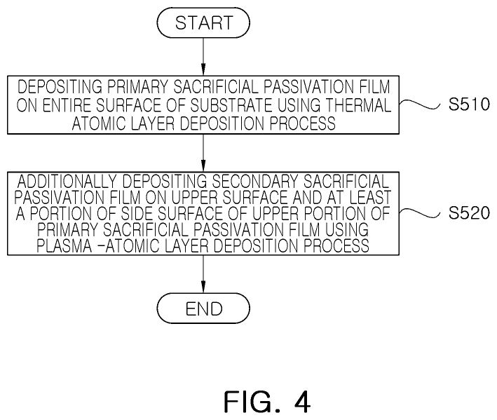

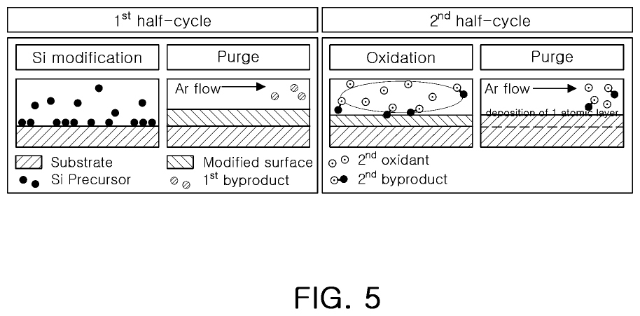

FIGS. 3 and 4 illustrate a process and flow chart of a sacrificial passivation film 100 deposition method using a low-temperature ALD process according to an exemplary embodiment of the present disclosure. FIG. 5 illustrates one cycle of a sacrificial passivation film 100 deposition method using a low-temperature ALD process according to an exemplary embodiment of the present disclosure.

As an exemplary embodiment, as illustrated in FIG. 3, an amorphous carbon layer (ACL, 2) may be disposed as a mask of a silicon oxide-nitride-oxide-nitride layer (ONON layer, 1) in which a silicon oxide film and a silicon nitride film are stacked, and a multilayer film including silicon oxynitride (SiON) film as a mask of the ACL 2 may be disposed.

As an exemplary embodiment, the ACL 2 may form a portion of the CHM of the ONON layer 1 by performing trench etching until a region without a photoresist (PR) pattern has a predetermined width.

As illustrated in FIGS. 3 and 4, the low-temperature ALD sacrificial passivation film deposition method according to an exemplary embodiment of the present disclosure may include: depositing a primary sacrificial passivation film 110 on an entire surface of a substrate using a thermal ALD (T-ALD) process (5510); and additionally depositing a secondary sacrificial passivation film 120 on an upper surface and at least a portion of a side surface of an upper portion of the primary sacrificial passivation film 110 using a plasma-ALD (P-ALD) process (5520).

As a specific exemplary embodiment, when the ONON layer 1 or the ACL 2 is partially etched to form a mask or pattern, a primary sacrificial passivation film 110 or a secondary sacrificial passivation film 120 may be deposited on the mask or pattern.

Referring to FIG. 3, the sacrificial passivation film 100 may be deposited by performing a T-ALD process on the entire surface of the partially opened CHM (an upper surface and an side surface of SiON, an entire surface of ACL 2 exposed by etching), and furthermore, on an exposed upper surface of the ONON layer 1.

The conventional T-ALD process isotropically deposits a sacrificial protection film using thermal energy at a high temperature of 200° C. to 400° C. However, when a silylamine compound represented by the following Formula 1 is used as a silicon precursor in the T-ALD process according to an exemplary embodiment of the present disclosure, the T-ALD process may perform deposition at a low-temperature below 150° C.

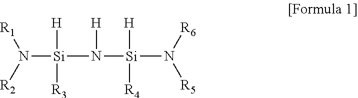

wherein R₁ to R₆ are each independently (C₁-C₅) alkyl or (C₂-C₅) alkenyl, or R₁ and R₂ and R₅ and R₆ may be independently connected to each other to form a ring.

In a low-temperature environment, after completing the deposition of the primary sacrificial passivation film 110 on the entire surface of the partially opened CHM (an upper surface and a side surface of SiON, and a side surface and a lower surface of ACL 2) using Formula 1, a secondary sacrificial passivation film 120 may be additionally deposited on the upper surface and the side surface of the upper portion of the CHM by continuously performing a second P-ALD process using the silicon precursor including Formula 1.

Meanwhile, as described above, a silicon precursor used for depositing the primary sacrificial passivation film in the T-ALD process and a silicon precursor used for depositing the secondary sacrificial passivation film in the P-ALD process may be the same as each other.

For example, both the T-ALD process and the P-ALD process may use a silylamine compound represented by Formula 1 as a silicon precursor, wherein R₁ to R₆ are each independently (C₁-C₅) alkyl or (C₂-C₅) alkenyl, or R₁ and R₂ and R₅ and R₆ may be independently connected to each other to form a ring.

Alternatively, as another exemplary embodiment, both the T-ALD process and the P-ALD process may use at least one of DIPAS, BDEAS, DSBAS, and BDIPADS as a silicon precursor.

As another exemplary embodiment, a silicon precursor used for depositing the primary sacrificial passivation film in the T-ALD process and a silicon precursor used for depositing the secondary sacrificial passivation film in the P-ALD process may be different from each other. For example, the T-ALD process may be performed using the silylamine compound as described above, and the P-ALD process may also use at least one of DIPAS, BDEAS, DSBAS, and BDIPADS as a silicon precursor.

According to an exemplary embodiment of the present disclosure, the method may further include: forming a trench by etching the substrate on which the sacrificial passivation film 100 is formed, and the sacrificial passivation film 100 may be removed during etching.

In other words, according to an exemplary embodiment of the present disclosure, the method may further include: forming a trench in a substrate by etching the substrate on which the primary sacrificial passivation film 110 and the secondary sacrificial passivation film 120 are deposited. In the forming of the trench in the substrate, the primary sacrificial passivation film 110 and the secondary sacrificial passivation film 120 may be removed.

The sacrificial passivation film 100 has a different deposition thickness for each pattern depth due to the influence of a manufacturing method of the secondary sacrificial passivation film 120 and may protect the upper surface and the side surface of the upper portion of the CHM, which are in frequent contact with plasma during trench etching, which is a subsequent process, for a longer period of time. Even if the secondary sacrificial passivation film 120 is etched, the primary sacrificial passivation film 110 may completely protect the side surface of the CHM. That is, in the etching process of etching the substrate, the secondary sacrificial passivation film 120 or the primary sacrificial passivation film 110 may be removed, and a portion of the secondary sacrificial passivation film 120, or all of the secondary sacrificial passivation film 120 and part of the primary sacrificial passivation film 110, or all of the secondary sacrificial passivation film 120 and all of the primary sacrificial passivation film 110 may be removed.

Specifically, as illustrated in FIG. 3, etching may be additionally performed on the partially opened CHM on which the primary sacrificial passivation film 110 and the secondary sacrificial passivation film 120 are deposited to form a trench perpendicular to the ACL 2, and in a process of forming the trench, the primary sacrificial passivation film 110 and the secondary sacrificial passivation film 120 may also be etched.

When the ACL 2, which is the material of the CHM, is etched to a target depth, all of the sacrificial passivation film 100 may be removed, or a portion of the sacrificial passivation film 100 may remain as illustrated in FIG. 3. FIG. 3 illustrates that only a portion of the primary sacrificial passivation film 110 remains, but this is only an exemplary embodiment, and portions of the primary sacrificial passivation film 110 and the secondary sacrificial passivation film 120 may also remain.

The remaining sacrificial passivation film 100 may be sufficiently removed with a plasma gas that performs etching without a separate additional process. In particular, the sacrificial passivation film 100 according to an exemplary embodiment of the present disclosure has a relatively high carbon content, like the ACL 2, and may be easily removed without a separate process due to the effect of an etching reaction caused by a combination with an oxygen plasma gas.

Meanwhile, according to an exemplary embodiment of the present disclosure, the depositing of the primary sacrificial passivation film 110 and the depositing of the secondary sacrificial passivation film 120 may be performed at a low-temperature of 150° C. or less, wherein the low-temperature may include a minus temperature.

That is, the depositing of the primary sacrificial passivation film 110 and the secondary sacrificial passivation film 120 may be performed at a temperature of 150° C. or less, which is lower than that of a conventional ALD process, and may further be performed at a temperature of 0° C. or less.

Specifically, conventional T-ALD is an ALD technique that performs deposition using thermal energy, and may be deposited at a temperature of at least 200° C. or more, and at a temperature lower than that, sufficient thermal energy to overcome an energy barrier may not be secured, so no reaction occurs.

However, according to an exemplary embodiment of the present disclosure, a silylamine compound may be used as a silicon precursor used in the T-ALD process, and the activation energy of the silylamine compound is very low, so that the reaction easily occurs even with thermal energy at a temperature lower than the conventional T-ALD process temperature.

Therefore, isotropic deposition may be performed by the T-ALD process not only at a temperature of 0 to 150° C. but also at a temperature of 0° C. or less due to the influence of the silylamine compound, which is a silicon precursor, to deposit the primary sacrificial passivation film 110 on the entire surface of the ACL 2 pattern.

In addition, as another exemplary embodiment of the present disclosure, the silicon precursor used in the T-ALD process may include at least one of DIPAS, BDEAS, DSBAS, and BDIPADS, and the silicon precursor may be used in the P-ALD process. The silicon precursor described above may have a similar effect to that of using the silylamine compound as a silicon precursor.

Even when the silicon precursor according to another exemplary embodiment of the present disclosure is used in the T-ALD process, the reaction is activated at a low-temperature of 150° C. or less, and deposition can be performed.

Meanwhile, according to an exemplary embodiment of the present disclosure, the primary sacrificial passivation film 110 or the secondary sacrificial passivation film 120 is deposited on the entire surface of the pattern by performing the T-ALD process or the P-ALD process in a plurality of cycles, and the number of the plurality of cycles may be 1 to 20 cycles. Here, one cycle of the P-ALD process or the T-ALD process is as illustrated in FIG. 5.

Specifically, one cycle of depositing an atomic-level monolayer includes a two-step reaction. The first reaction step is a physicochemical adsorption reaction (Si modification) between a silicon precursor (Si precursor) injected into a vacuum chamber and the substrate surface, and may form a modified surface to which a portion of the silicon precursor is bonded. The reaction may occur as a self-limiting reaction and ends spontaneously, and then an inert gas may be flowed to purge 1^{st} byproducts and unreacted silicon precursors generated after the reaction of the silicon precursor. In the second reaction step, a reactant, for example, an oxidant such as ozone gas, hydrogen peroxide gas, or oxygen plasma may be injected/generated into the modified surface to form a SiO₂ atomic layer on the substrate surface through a chemical substitution reaction (oxidation) between the modified surface and the oxidant. Similarly, an inert gas may be flowed to remove 2^{nd} byproducts and unreacted oxidants generated after the reaction.

In other words, in the case of the ALD process of SiO₂, one process cycle may be completed through the Si modification-purge-oxidation-purge process, and the meaning of the T-ALD process and the P-ALD process may be determined by the energy source (heat, plasma) used in the second reaction step.

In addition, the primary sacrificial passivation film 110 or the secondary sacrificial passivation film 120 may have a thickness of 1 to 20 Å.

The T-ALD process or the P-ALD process is repeatedly performed from 1 to 20 cycles, and the sacrificial passivation film 100 manufactured by the T-ALD process or the P-ALD process using the silylamine compound has a high growth rate, such that 1 Å deposition per cycle is possible, and a film thickness of 1 to 20 Å may be formed during the cycle.

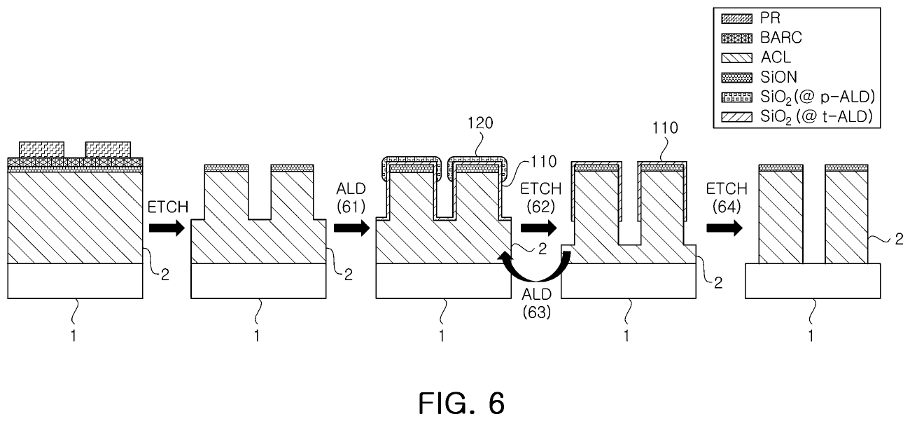

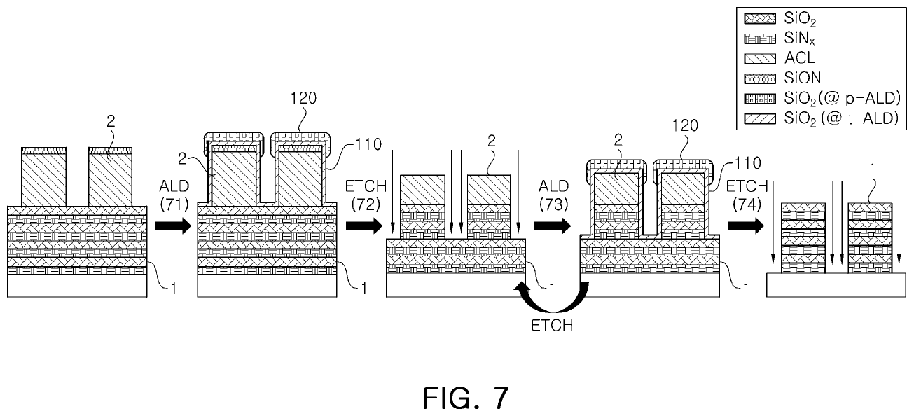

FIG. 6 is a view illustrating application of a trench etching method using a low-temperature ALD process according to an exemplary embodiment of the present disclosure to a CHM manufacturing process. FIG. 7 is a view illustrating application of a trench etching method using a low-temperature ALD process according to an exemplary embodiment of the present disclosure to a CHH manufacturing process.

As illustrated in FIGS. 6 and 7, a trench etching method using a low-temperature ALD process according to another exemplary embodiment of the present disclosure may include: a trench etching method using a low-temperature atomic layer deposition (ALD) process may include: depositing a target layer on a substrate; etching a portion of the target layer; and completing etching of the target layer, wherein the etching of the portion of the target layer may include: depositing a primary sacrificial passivation film 110 on an entire surface of the target layer using a thermal ALD (T-ALD) process; and additionally depositing a secondary sacrificial passivation film 120 on an upper surface and a side surface of an upper portion of the primary sacrificial passivation film 110 using a plasma-ALD (P-ALD) process.

The etching of the portion of the target layer may include: forming a pattern including CHM and CHH by performing etching until a region without a mask pattern of the substrate has a predetermined width before depositing the sacrificial passivation film 100. The completing of the etching may include: forming a trench to a target depth by vertically additionally etching the CHM and CHH materials on which the sacrificial passivation film 100 is deposited.

For example, the method may include: forming a pattern by etching a substrate; depositing a primary sacrificial passivation film 110 on an entire surface of the pattern using a T-ALD process; additionally depositing a secondary sacrificial passivation film 120 on an upper surface and a side surface of an upper portion of a pattern on which the primary sacrificial passivation film 110 is deposited using a P-ALD process; and forming a trench by etching perpendicular to the substrate on which the sacrificial passivation films 110 and 120 are deposited.

As an exemplary embodiment, referring to FIG. 6, the ONON layer 1 may be alternately disposed, the ACL 2 may be disposed thereon, and SiON, bottom anti-reflection coating (BARC), and PR patterns may be sequentially disposed thereon.

After etching perpendicular to the ACL 2 of a region without the PR pattern to form a portion of the CHM, a primary sacrificial passivation 110 may be deposited on the entire surface of the ACL 2 pattern through a low-temperature ALD process 61, and a secondary sacrificial passivation film 120 may be deposited on the upper surface and a side surface of an upper portion of the CHM on the primary sacrificial passivation film 110.

That is, the primary sacrificial passivation film 110 and the secondary sacrificial passivation film 120 may be deposited on the target layer of which the portion is etched. When etching is performed to form a trench, the sacrificial passivation film 100 may be deposited so that a vertically formed hole is formed and maintained in a vertical state.

Then, etching may be performed on the target layer on which the primary sacrificial passivation film 110 and the secondary sacrificial passivation film 120 are deposited. At this time, the target layer may include the ONON layer 1 or ACL 2 of the 3D-NAND gate.

According to an exemplary embodiment of the present disclosure, forming the primary sacrificial passivation film 110 and the secondary sacrificial passivation film 120 may be performed at a temperature of 0° C. to 150° C. or less, or at a minus temperature of 0° C. or less. That is, it may be performed at a low-temperature of 150° C. or less, including minus temperature.

Meanwhile, according to an exemplary embodiment of the present disclosure, a silicon precursor used for depositing the primary sacrificial passivation film 100 in the T-ALD process and a silicon precursor used for depositing the secondary sacrificial passivation film 120 in the P-ALD process may be the same as each other.

As an exemplary embodiment, a T-ALD process may be performed to form the primary sacrificial passivation film 110, and the silicon precursor used in the T-ALD process may be a silylamine compound represented by the following Formula 1, wherein R₁ to R₆ are each independently (C₁-C₅) alkyl or (C₂-C₅) alkenyl, or R₁ and R₂ and R₅ and R₆ may be independently connected to each other to form a ring.

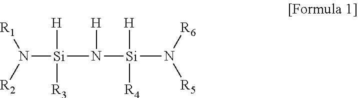

Here, the silylamine compound described above may also be used in the P-ALD process.

Alternatively, as another exemplary embodiment, the silicon precursor used in the T-ALD process and the P-ALD process may be at least one of DIPAS, BDEAS, DSBAS, and BDIPADS, and may be the same as each other.

According to another exemplary embodiment of the present disclosure, the T-ALD process may use a silylamine compound, and the P-ALD process may use at least one of DIPAS, BDEAS, DSBAS, and BDIPADS as a silicon precursor. Different silicon precursors may also be used in the T-ALD process and the P-ALD process.

Therefore, when the etching process 62 is performed on the ACL 2 on which the primary sacrificial passivation film 110 and the secondary sacrificial passivation film 120 are deposited, the ACL 2 in which the trench is not formed may be etched to a target depth during the etching process, and the sacrificial passivation film 100 may also be removed. The sacrificial passivation film 100 to be removed may be the primary sacrificial passivation film 110 or the secondary sacrificial passivation film 120.

Here, the trench of the ACL 2 may be formed deeply, and before the side surface of the ACL 2 exposed by etching is etched to a predetermined width or more, the primary sacrificial passivation film 110 surrounding the entire surface of the CHM may be deposited again through the low-temperature ALD process 63 described above, and a secondary sacrificial passivation film 120 may deposited on the upper surface and the side surface of the upper portion of the primary sacrificial passivation film 110 to prevent loss of CHM to the plasma gas for etching.

That is, the etching process 62 and the ALD process 63 may be repeatedly performed until the ACL 2 is etched to a desired depth.

When a trench etching process 64 for the ACL 2 is completed, the sacrificial passivation film 100 may also be etched and removed together with the ACL 2 etching without going through a separate sacrificial passivation film 100 removal process.

In other words, when the primary sacrificial passivation film 110 or the secondary sacrificial passivation film 120 deposited in the etching of the portion of the target layer is removed, a process of depositing and etching the primary sacrificial passivation film 110 or the secondary sacrificial passivation film 120 may be repeatedly performed. A primary sacrificial passivation film 110 or a secondary sacrificial passivation film 120 may be deposited before etching the target layer, or may be deposited after partially etching to form a vertical structure, or may be deposited again when all of the sacrificial passivation film 100 is removed during etching. Therefore, the sacrificial passivation film 100 may be deposited multiple times even during etching.

Also, as an exemplary embodiment, in the completing of the etching of the target layer, the sacrificial passivation film 100 may be removed. Instead of performing a separate sacrificial passivation film removal process, the sacrificial passivation film 100 may be removed during the etching process for the target layer, and the sacrificial passivation film 100 may not remain after the etching process is completed.

As an exemplary embodiment, if the sacrificial passivation film 100 remains even after the etching process 64, process conditions such as concentration, flow rate, pressure, and plasma power of the injected oxygen gas may be adjusted so that the sacrificial passivation film 100 may be completely removed.

Alternatively, as illustrated in FIG. 7, even when the ONON layer 1 is etched after the etching of the ACL 2 is completed, the method of depositing the sacrificial passivation film 100 according to an exemplary embodiment of the present disclosure may be applied.

Specifically, the primary sacrificial passivation film 110 and the secondary sacrificial passivation film 120 may be deposited by performing the low-temperature ALD process 71 described above on the ACL 2 etched on the upper surface of the ONON layer 1.

In a state where the primary sacrificial passivation film 110 and the secondary sacrificial passivation film 120 are deposited, the etching process 72 may be performed on the ONON layer 1, and when all of the sacrificial passivation film 100 is removed during the etching process 72 or the trench of the ONON layer 1 exposed by the etching process 72 reaches a predetermined width, the ALD process 73 may be performed again to deposit the primary sacrificial passivation film 110 and the secondary sacrificial passivation film 120.

That is, the etching process 72 and the ALD process 73 may be repeatedly performed until the ONON layer is etched to a desired depth.

Then, when the etching process 74 for the ONON layer 1 is completed, the sacrificial passivation film 100 may also be etched and removed together with the ONON layer 1 etching without going through a separate sacrificial passivation film 100 removal process.

If the sacrificial passivation film 100 remains even after the etching process 74, process conditions such as concentration, flow rate, pressure, and plasma power of the injected fluorine-based etchant may be adjusted so that the sacrificial passivation film 100 may be completely removed.

In other words, forming a trench by vertically etching the CHM according to an exemplary embodiment of the present disclosure may include forming a trench by etching the ONON layer 1 of the 3D-NAND gate, and in the step of vertically etching the ACL layer 2 and the ONON layer 1 to form a trench, the sacrificial passivation film 100 may be removed.

In addition, the primary sacrificial passivation film 110 and the secondary sacrificial passivation film 120 may be deposited to suppress a bow phenomenon that may occur during an etching process of a high aspect ratio, in addition to the etching of FIGS. 6 and 7.

Meanwhile, the above-described exemplary embodiment described using the ONON layer 1 and the ACL 2 in which the CHH and CHM in a 3D-NAND flash memory manufacturing process are formed as target layers. However, the target layer means a portion of a trench structure of a high aspect ratio formed by high aspect ratio etching, and a sacrificial passivation film deposition method or a trench etching method using a low-temperature ALD process according to an exemplary embodiment of the present disclosure may be applied as long as the target layer is a portion of the trench structure of a high aspect ratio.

That is, the trench structure of a high aspect ratio may include at least a channel hole (CHH), a channel hole mask (CHM), and an amorphous carbon layer (ACL) in the 3D-NAND flash memory manufacturing process, which is an exemplary embodiment and the claims of the present disclosure are not limited thereto.

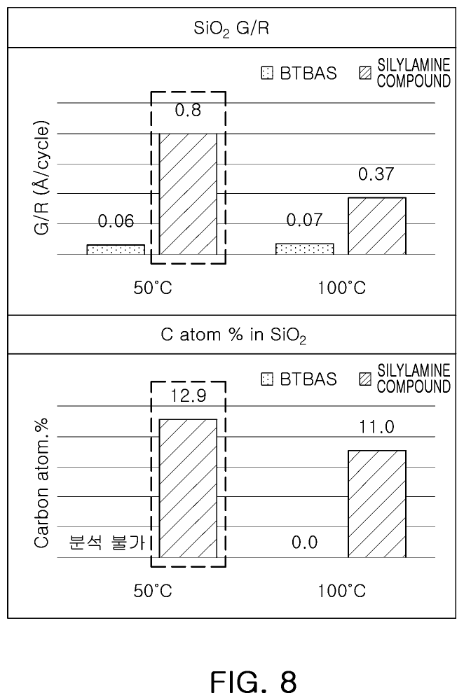

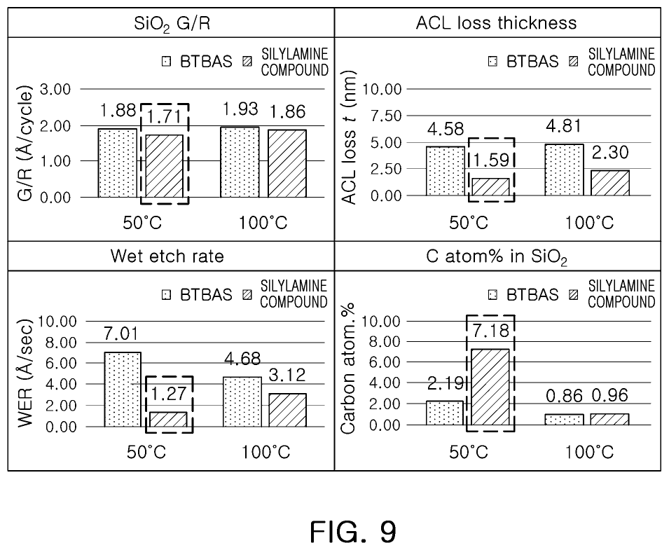

FIG. 8 is graphs illustrating experimental results by performing a T-ALD process according to an exemplary embodiment of the present disclosure using BTBAS and a silylamine compound. FIG. 9 is graphs comparing experimental results obtained by performing a P-ALD process according to an exemplary embodiment of the present disclosure using BTBAS and a silylamine compound.

FIG. 8 in detail, is graphs illustrating a growth rate (G/R) and a carbon content of the primary sacrificial passivation film 110 formed of each silicon precursor for each temperature by comparing a T-ALD process performed using conventional BTBAS as a silicon precursor and a T-ALD process performed using a silylamine compound as a silicon precursor, respectively.

Referring to FIG. 8, in the T-ALD process using BTBAS, which is a conventional silicon precursor, in relation to the growth rate for each temperature, 0.06 Å may be deposited during one cycle at 50° C. and 0.07 Å may deposited during one cycle at 100° C., so an atomic layer of approximately 0.06 to 0.07 Å may be deposited within 150° C.

It is considered that the T-ALD process does not substantially deposited at 0.1 Å/cycle or less. It was confirmed that the T-ALD process is manufacturing method that is not commercially applicable when compared with the growth rate (0.5 Å/cycle or more) of the ALD process required from a commercial point of view.

On the other hand, in a low-temperature T-ALD process using a silylamine compound as a silicon precursor, 0.8 Å was deposited during one cycle at 50° C. and 0.37 Å was deposited during one cycle at 100° C., confirming that the growth rate increased with decreasing temperature.

That is, through a T-ALD process having a growth rate of 0.8 Å/cycle or more using a silylamine compound, a low-temperature process technology that is easy to apply commercially was confirmed through the exemplary embodiment, and the entire surface of the target pattern including the ACL 2 may be protected from the above process.

In addition, regarding the carbon content in the primary sacrificial passivation film 110, it was confirmed that the T-ALD process using conventional BTBAS manufacture a high-purity SiO₂ film with a carbon content of 0% based on a process of 100° C., whereas the T-ALD process using the silylamine compound based on the same process temperature has a significant amount of carbon content of 10.9%.

The high-purity sacrificial passivation film 100, which is a result of the conventional BTBAS, has a very dense crystal lattice structure and thus remains even after trench etching, and a separate high-temperature annealing process is required to remove the sacrificial passivation film 100.

On the other hand, when the sacrificial passivation film 100 containing a high amount of carbon by the silylamine compound is etched by oxygen plasma, the higher the carbon content, the easier the etching reaction. As a result, in an anisotropic etching process for ACL 2 mask patterning, due to the straightness of the oxygen ions, the primary sacrificial passivation film 110 existing under the partially trenched ACL 2 may be easily removed and trench etching of the ACL 2 may be continuously performed.

That is, when a trench etching process including a plasma oxidation reaction is performed, the primary sacrificial passivation film 110 manufactured by a low-temperature T-ALD process using a silylamine compound may be easily removed in the etching process, so there is no need to go through a separate sacrificial passivation film 100 removal process, and the etching process of the ACL 2 is not affected.

Therefore, the carbon content of the sacrificial passivation film prepared by the silylamine compound according to an exemplary embodiment of the present disclosure may have 10.9% as illustrated in FIG. 8, and may have a level of 11.0% to 12.9% even considering process condition variations.

However, the numerical value is the carbon content of the sacrificial passivation film 100 obtained through the T-ALD process using a silylamine compound represented by Formula 1 in which R₁ to R₆ are independently alkyl (C1) as a silicon precursor, and in addition, on the premise that alkyl included in the silylamine compound may have 2 to 7 carbons and alkenyl may have 2 to 7 carbons, the carbon content of the sacrificial passivation film 100 obtained in the low-temperature process may be higher.

For example, the carbon content may be increased as a process temperature in which the sacrificial passivation film 100 is deposited is lowered or the carbon number of alkyl or alkenyl of the silylamine compound is increased, and may have a carbon content of up to 20%. Conversely, as the process temperature is increased to a maximum of 150° C. and the carbon number of the alkyl or alkenyl of the silylamine compound is lowered, the carbon content may be lowered and the carbon content may be at least 0.96%.

Therefore, the carbon content of the sacrificial passivation film manufactured by the silylamine compound may be 0.96 to 20%. The numerical value is an exemplary embodiment, and the carbon content measured in the primary sacrificial passivation film 110 formed through the T-ALD process performed using a silylamine compound as a silicon precursor within 150° C. may be included in the scope of the present disclosure.

In addition, FIG. 9 is in detail, graphs illustrating a growth rate (G/R), a loss thickness of the ACL 2 by a P-ALD process, a wet etching rate of the secondary sacrificial passivation film 120, and a carbon content for each temperature, in order to compare a P-ALD process using the conventional BTBAS and a low-temperature P-ALD process using a silylamine compound.

Referring to FIG. 9, in a P-ALD process using the conventional BTBAS, in relation to the growth rate for each temperature, 1.88 Å may be deposited during one cycle at 50° C. and 1.93 Å may be deposited during one cycle at 100° C., so approximately 1.88 to 1.93 Å level may be deposited within 150° C.

On the other hand, in the P-ALD process using a silylamine compound, 1.71 Å may be deposited during one cycle at 50° C. and 1.86 Å may be deposited during one cycle at 100° C., so an atomic layer of 1.71 to 1.86 Å may be deposited within 150° C.

Therefore, in the low-temperature P-ALD process, any one of BTBAS and a silylamine compound may be used as a silicon precursor to have a high growth rate.

On the other hand, in relation to the loss thickness of the ACL 2 on which the secondary sacrificial passivation film 120 is disposed thereon for each temperature, a low-temperature P-ALD process using the conventional BTBAS lost a thickness of 4.58 to 4.81 nm, whereas a P-ALD process using a silylamine compound lost a thickness of 1.59 to 2.30 nm.

It was confirmed from the above results that the low-temperature P-ALD process using the silylamine compound compared to the conventional BTBAS reduced the loss of ACL 2 by 50% and was excellent in protecting a sidewall of ACL 2.

In addition, as in an exemplary embodiment of the present disclosure, since the primary sacrificial passivation film 110 is formed, damage to the target material including the ACL 2 may be further reduced. However, the primary sacrificial passivation film 110 may be manufactured to a very thin thickness at the level of 1 to 20 cycles, and considering the damage caused by the penetration of oxygen plasma during the manufacturing process of the secondary sacrificial passivation film 120, the low-temperature P-ALD process using the silylamine compound may be more advantageous.

A wet etching rate for each temperature may be evaluated by immersing the secondary sacrificial passivation film 120 manufactured by the P-ALD process using the conventional BTBAS and a silylamine compound in hydrogen fluoride (HF) for a certain period of time and measuring a etched thickness to calculate an etching rate.

As illustrated in FIG. 9, the WER of the secondary sacrificial passivation film 120 manufactured from the conventional BTBAS was 7.01 Å/sec at 50° C. and 4.68 Å/sec at 100° C., whereas the WER of the secondary sacrificial passivation film 120 manufactured from a silylamine compound was 1.27 Å/sec at 50° C. and 3.12 Å/sec at 100° C. Thus, it can be seen that the secondary sacrificial passivation film 120 formed of a silylamine compound at a low-temperature of 50° C. has the best chemical resistance to the fluorine-based etchant.

The above result, in relation to the result of the carbon content of the exemplary embodiment of FIG. 9, may be considered to be one of the causes of the carbon content affecting the WER since carbon, which is known to have excellent chemical resistance to fluorine-based etchants, is included in a significant amount of 7.18% in the secondary sacrificial passivation film 120 manufactured by the silylamine compound.

In general, fluorine-based gas may be used as an etchant in an etching process of a silicon oxide film and a silicon nitride film, and may also be used in trench etching of the ONON layer 1 to form CHH corresponding to the exemplary embodiment of FIG. 7.

In particular, the trench etching process of the ONON layer 1 has a very large etching aspect ratio, so in order to perform etching to a target depth while maintaining a target trench width, the sacrificial passivation film 100 needs to be durable so that the sidewall of the ONON layer is not lost.

Therefore, it is shown that a low etching rate for the fluorine-based etchant of the secondary sacrificial passivation film 120 manufactured by the silylamine compound may serve as the sacrificial passivation film 100 suitable for the etching process of the silicon oxide film and the silicon nitride film such as the ONON layer 1 described above.

In addition, the low etching rate of the fluorine-based etchant may form a thin thickness of the sacrificial passivation film 100, and the possibility of remaining the sacrificial passivation film 100 after the etching process is very low, and as a result, productivity improvement due to a reduction in process time may be expected.

Finally, in relation to the carbon content in the secondary sacrificial passivation film 120 formed of each silicon precursor, the conventional P-ALD process using BTBAS was 2.19% at 50° C. and 0.86% at 100° C., whereas the P-ALD process using the silylamine compound was 7.18% at 50° C. and 0.96% at 100° C.

The secondary sacrificial passivation film 120 manufactured by the low-temperature P-ALD process using the silylamine compound has a higher carbon content than the secondary sacrificial passivation film 120 manufactured by the low-temperature P-ALD process using the conventional BTBAS, and thus, it may be easy to remove the sacrificial passivation film 100 remaining after the etching process using oxygen plasma.

The carbon content of the primary sacrificial passivation film 110 and the secondary sacrificial passivation film 120 manufactured by the silylamine compound according to an exemplary embodiment of the present disclosure as illustrated in FIGS. 8 and 9 may be 0.96% to 12.9%.

However, the numerical value is the carbon content of the sacrificial passivation film obtained through the T-ALD process and the P-ALD process using a silylamine compound represented by Formula 1 in which R₁ to R₆ are independently alkyl (C1) as a silicon precursor, and in addition, on the premise that alkyl included in the silylamine compound may have 2 to 7 carbons and alkenyl may have 2 to 7 carbons, the carbon content values may be even higher at a low-temperature. The content described above will not be repeatedly described.

Therefore, the numerical value is an exemplary embodiment, and any carbon content measured in the sacrificial passivation film 100 formed through the T-ALD process or the P-ALD process using the silylamine compound within 150° C. may be included in the scope of the present disclosure.

That is, a high carbon-containing sacrificial passivation film 100 formed through the T-ALD or P-ALD process using the silylamine compound according to an exemplary embodiment of the present disclosure may easily remove the remaining sacrificial passivation film 100 with oxygen plasma used in the trench etching of the ACL 2, and the trench etching of the ONON layer 1, which is a subsequent process of the ACL 2 etching may completely protect the sidewall of the trenched ONON layer 1 by lowering the etching rate of the sacrificial passivation film 100 due to chemical resistance to the fluorine-based etchant.

Meanwhile, according to an embodiment of the present disclosure, a semiconductor processing apparatus for performing the sacrificial passivation film 100 deposition method using the low-temperature ALD process described above or the trench etching method using the low-temperature ALD process described above may be provided.

According to an exemplary embodiment of the present disclosure, etching of a high aspect ratio including deposition of the sacrificial passivation film 100 and trench etching of the ACL 2 or ONON layer 1 can be performed in one chamber, and no separate device is required to perform each process.

That is, as a one-chamber type, the deposition method of the sacrificial passivation film 100 using the low-temperature ALD process or the trench etching method using the low-temperature ALD process described above may be performed in one chamber. When the silicon precursor is the same, process parameters such as temperature conditions do not significantly differ, and thus, it may be performed in one chamber.

Alternatively, as another exemplary embodiment, the semiconductor processing apparatus may include: a first chamber for depositing a primary sacrificial passivation film 110 on a target layer, and a second chamber for depositing a secondary sacrificial passivation film 120 on the primary sacrificial passivation film 110, wherein the first chamber and the second chamber are different.

If the silicon precursors performed in the T-ALD and P-ALD processes are different, the process may be performed in a two-chamber type. At this time, the etching may be performed on the target layer in the first chamber or the second chamber.

Through this, a separate transfer for deposition or removal of the sacrificial passivation film 100 is not required during the etching process, and an additional process for removing the sacrificial passivation film 100 is also not required, so work efficiency may be improved, and yield may be improved by preventing bowing.

In addition, in describing the present disclosure, the semiconductor processing apparatus may include a control unit that performs the method described above, wherein the control unit may be implemented in various ways, for example, a processor, program instructions executed by the processor, software modules, microcodes, computer program products, logic circuits, application-specific integrated circuits, firmware, and the like.

As set forth above, according to the present disclosure, it is possible to improve work efficiency by performing sacrificial passivation film deposition and trench etching through T-ALD and P-ALD processes in one etching chamber, and to overcome a process technical limitations of the low-temperature T-ALD process by using a silylamine compound.

According to the present disclosure, it is possible to prevent an abnormal phenomenon such as bowing and tapering to solve chronic problems in semiconductor device manufacturing.

In addition, in describing the present disclosure, the semiconductor processing apparatus may include a control unit that performs the method described above, wherein the control unit may be implemented in various ways, for example, a processor, program instructions executed by the processor, software modules, microcodes, computer program products, logic circuits, application-specific integrated circuits, firmware, and the like.

While the exemplary embodiments have been shown and described above, it will be apparent to those skilled in the art that modifications and variations could be made without departing from the scope of the present disclosure as defined by the appended claims.

What is claimed is:

1. A sacrificial passivation film deposition method using a low-temperature atomic layer deposition (ALD) process, comprising:
depositing a primary sacrificial passivation film on an entire surface of a substrate using a thermal ALD (T-ALD) process; and
additionally depositing a secondary sacrificial passivation film on an upper surface and at least a portion of a side surface of an upper portion of the primary sacrificial passivation film using a plasma-ALD (P-ALD) process.

2. The sacrificial passivation film deposition method of claim 1, wherein the depositing of the primary sacrificial passivation film and the depositing of secondary sacrificial passivation film are performed at a low-temperature of 150° C. or less.

3. The sacrificial passivation film deposition method of claim 2, wherein the low-temperature includes a temperature of 0° C. or less.

4. The sacrificial passivation film deposition method of claim 1, wherein a silicon precursor used for depositing the primary sacrificial passivation film in the T-ALD process and a silicon precursor used for depositing the secondary sacrificial passivation film in the P-ALD process are the same as each other.

5. The sacrificial passivation film deposition method of claim 4, wherein the silicon precursor is a silylamine compound represented by the following Formula 1: 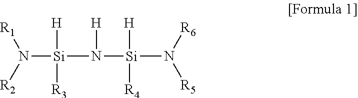
wherein R₁ to R₆ are each independently (C₁-C₅) alkyl or (C₂-C₅) alkenyl, or R₁ and R₂ and R₅ and R₆ are independently connected to each other to form a ring.

6. The sacrificial passivation film deposition method of claim 4, wherein the silicon precursor is at least one of DIPAS, BDEAS, DSBAS, and BDIPADS.

7. The sacrificial passivation film deposition method of claim 1, wherein a silicon precursor used for depositing the primary sacrificial passivation film in the T-ALD process and a silicon precursor used for depositing the secondary sacrificial passivation film in the P-ALD process are different from each other.

8. The sacrificial passivation film deposition method of claim 5, wherein a carbon (C) content of the sacrificial passivation film manufactured by the silylamine compound is 0.96 to 20%.

9. The sacrificial passivation film deposition method of claim 5, wherein the primary sacrificial passivation film or the secondary sacrificial passivation film has a thickness of 1 to 20 Å.

10. The sacrificial passivation film deposition method of claim 5, wherein the primary sacrificial passivation film or the secondary sacrificial passivation film is deposited on the entire surface of the substrate by performing the T-ALD process or the P-ALD process in a plurality of cycles, and the number of the plurality of cycles is 1 to 20 cycles.

11. A trench etching method using a low-temperature atomic layer deposition (ALD) process, comprising:
depositing a target layer on a substrate;
etching a portion of the target layer; and
completing etching of the target layer,
wherein the etching of the portion of the target layer includes:
depositing a primary sacrificial passivation film on an entire surface of the target layer using a thermal ALD (T-ALD) process; and
additionally depositing a secondary sacrificial passivation film on an upper surface and a side surface of an upper portion of the primary sacrificial passivation film using a plasma-ALD (P-ALD) process.

12. The trench etching method of claim 11, wherein the primary sacrificial passivation film and the secondary sacrificial passivation film are deposited on the target layer of which the portion is etched.

13. The trench etching method of claim 11, wherein the target layer is a portion of a trench structure of a high aspect ratio formed by high aspect ratio etching, and the trench structure of the high aspect ratio includes at least a channel hole (CHH), a channel hole mask (CHM), and an amorphous carbon layer (ACL) in a 3D-NAND flash memory manufacturing process.

14. The trench etching method of claim 11, wherein the depositing of the primary sacrificial passivation film and the depositing of the secondary sacrificial passivation film is performed at a low-temperature of 150° C. or less.

15. The trench etching method of claim 11, wherein a silicon precursor used for depositing the primary sacrificial passivation film in the T-ALD process and a silicon precursor used for depositing the secondary sacrificial passivation film in the P-ALD process are the same as each other.

16. The trench etching method of claim 15, wherein the silicon precursor is a silylamine compound represented by the following Formula 1: 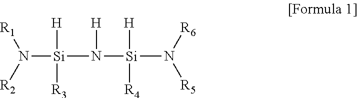
wherein R₁ to R₆ are each independently (C₁-C₅) alkyl or (C₂-C₅) alkenyl, or R₁ and R₂ and R₅ and R₆ are independently connected to each other to form a ring.

17. The trench etching method of claim 11, wherein when the deposited primary sacrificial passivation film or the secondary sacrificial passivation film deposited in the etching of the portion of the target layer is removed, a process of depositing and etching the primary sacrificial passivation film or the secondary sacrificial passivation film are repeatedly performed.

18. The trench etching method of claim 11, wherein in the completing of the etching of the target layer, the primary sacrificial passivation film and the secondary sacrificial passivation film are removed.

19. A semiconductor processing apparatus that performs the trench etching method using the low-temperature atomic layer deposition (ALD) process of claim 11, comprising:
a first chamber depositing the primary sacrificial passivation film on the target layer, and
a second chamber depositing the secondary sacrificial passivation film on the primary sacrificial passivation film.

20. The semiconductor processing apparatus of claim 19, wherein the first chamber and the second chamber are the same chamber, and
the etching is performed on the target layer in the first chamber or the second chamber.
